(19) United States
(12) Patent Application Publication
(10) Pub. No.: US 2012/0018892 A1
(43) Pub. Date: Jan. 26, 2012

(54) SEMICONDUCTOR DEVICE WITH INDUCTOR AND FLIP-CHIP

(76) Inventor: MEHDI FREDERIK SOLTAN, Hong Kong (HK)

(21) Appl. No.: 12/841,967

(22) Filed: Jul. 22, 2010

(51) Int. Cl. H01L 23/498; H01L 21/768

(52) U.S. Cl. 257/773; 438/613; 257/E23.068; 257/E21.589

(57) ABSTRACT

Semiconductor devices comprising a flip-chip having vias to connect front and back surfaces and a bondwire connected to the via or the back surface.

Provision is made for packaging the flip-chip with a package substrate.

Further aspects of the invention provide for inductance within the semiconductor device.

### RELATED APPLICATIONS

None.

### FIELD OF THE INVENTION

The present invention generally relates to electronic devices and circuits. The invention more particularly relates to implementation of inductive components used within and/or in conjunction with semiconductor devices that exploit flip-chip packages and related and allied materials and manufacturing techniques. Devices having similar or analogous topologies may fall within the general scope of the invention. The invention may be used in RF (Radio Frequency) and commonly microwave analog devices and find particular utility in such devices; however it may also find application in other types of electronic circuits and devices, such as mixed-signal devices.

### BACKGROUND OF THE INVENTION

Modernly, wireless communication products such as cellular radiotelephones are compact, lightweight, low power, incorporate sophisticated energy management and have a very competitive unit cost. Nonetheless, there is an unremitting drive to improvement in all those parameters, especially manufacturing costs, of which fab (active device fabrication) cost is a significant proportion.

In the above-referenced types of applications, although mixed signal devices are found in the art, commonly one or two semiconductor devices, or chips, are dedicated to the analog part of the circuit. Typically most of the analog circuit operates at RF, commonly in a microwave region. Flip-chip technologies have been preferred in some cases due to smaller path lengths. Alternative approaches, such as utilizing packages with lead frames and associated bond wires, are likely to be relatively more complex to fab (fabricate).

In previous developments, bond wires have been used to provide inductive complements, such as are used in resonant circuits, transmission lines and DC (direct current) chokes and more. Bondwires (or bond wires) used as inductors typically have a better Q (Quality factor) than on-chip spiral inductors and so are often preferred.

Q (Quality factor) is a particularly important property of an inductor since it directly affects the performance of RF circuits as is well known in the art. Inductors formed as bondwires have relatively high Q values, typically more than 50. Conversely, on-chip spiral inductors have a lower Q, typically less than 10. For comparison purposes it may be noted that discrete component inductors have Q's that typically lie between 50 and 200. Bondwire inductors used as RF components with leaded semiconductor packages are well known in the art and have low associated costs. Discrete component inductors increase the bill of materials part count and so are relatively expensive to use.

Devices and circuits that incorporate flip-chip based semiconductor components have no need for bond-wires for purposes of interconnect. Instead a conductive bump to substrate-pad form of bonding may be used to provide for quite short signal conductor lengths thus resulting in significant design advantage, especially at ever-higher operating frequencies. Manufacturing techniques for conductively and mechanically bonding bumps on semiconductor devices to other components are well known in the art. However, since flip-chips rarely (if ever) use lead-frames and hence dispense with bondwires, some other form of providing inductive components must be used. Since an inductor with a high Q factor is typically desired, off-chip discrete component inductors have been used in preference to on-chip (spiral or similar) inductors with their low Q values.

The many advantages of flip-chip technologies are well known, including factors such as reduced inductance in signal paths, shorter interconnect lengths, and also higher interconnect density, smaller package size, and possible reduction in die size. Prices and costs are becoming increasingly competitive in at least some configurations.

The invention provides a device and method to manufacture incorporated inductance features used with flip-chip semiconductors having a better price/performance than has been possible with previous implementations. Thus, an advantage of the invention is that a better performing semiconductor based circuit that includes inductive component(s) may be built for a particular cost, or alternatively if a particular performance is specified then the overall cost may be lower than with products based on previously developed solutions.

### SUMMARY OF THE INVENTION

The present invention provides for an active semiconductor based device incorporating an inductive circuit.

According to an aspect of the present invention an embodiment of the invention may provide a semiconductor device comprising a die with a via there through, the die having inter-connections on one face and a bondwire connected to the via at the opposite face of the die.

According to a further aspect of the invention the inter-connections are flip-chip bumps.

According to a further aspect of the invention the bondwire is designed to provide a low loss DC (direct current) path while acting as an RFC (radio frequency choke).

According to a still further aspect of the invention the bondwire is designed to resonate at the operating RF (radio frequency) of the semiconductor device.

### BRIEF DESCRIPTION OF THE DRAWINGS

The aforementioned and related advantages and features of the present invention will become better understood and appreciated upon review of the following detailed description of the invention, taken in conjunction with the following drawings, which are incorporated in and constitute a part of the specification, illustrate an embodiment of the invention and wherein like numerals represent like elements, and in which:

FIG. 1 shows a cross sectional view of a manufactured device and structure according to an embodiment of the invention;

FIG. 2 shows a cross sectional view of package substrate according to an embodiment of the invention;

FIG. 3 shows a flip-chip according to an embodiment of the invention;

FIG. 4 shows a cross-sectional view of a complete device according to an embodiment of the invention.

### DETAILED DESCRIPTION OF THE INVENTION

The numerous components shown in the drawings are presented to provide a person of ordinary skill in the art a thorough, enabling disclosure of the present invention. The description of well-known components is not included within this description so as not to obscure the disclosure or take away or otherwise reduce the novelty of the present invention and the main benefits provided thereby.

Embodiments of the disclosure presented herein provide manufactures and methods of building them. In the following detailed description, references are made to the accompanying drawings that form a part hereof, and in which are shown by way of illustration specific embodiments or examples. Referring now to the drawings, in which like numerals represent like elements throughout the several figures, aspects of an exemplary operating environment and the implementations provided herein will be described.

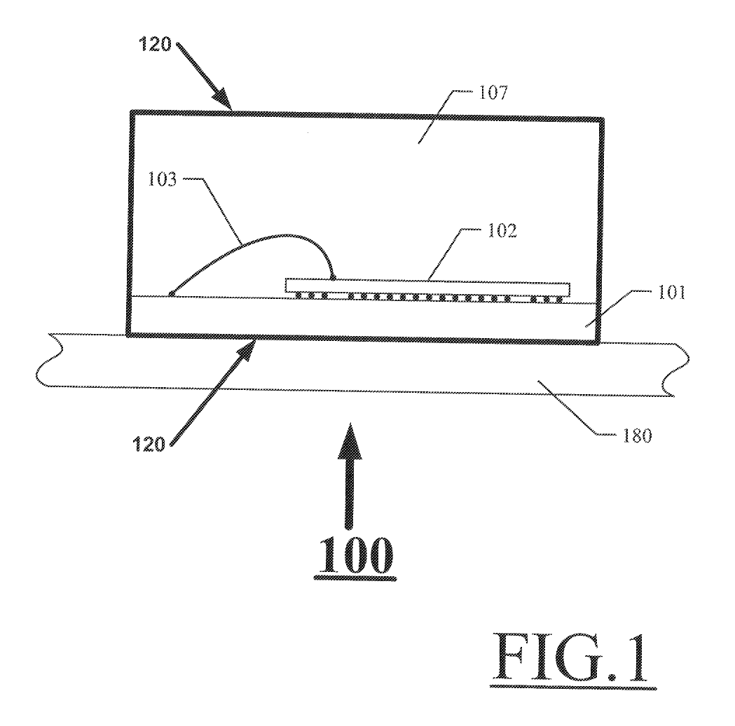

Exemplary embodiments of the present invention will now be described with reference to the figures. FIG. 1 shows a cross sectional view of a manufactured device 120 deployed as part of an assembly 100 by attachment to a structure 180 which may be a PCB (printed circuit board) or a PWA (printed wire assembly) according to an embodiment of the invention.

As shown, in this exemplary embodiment of the invention, manufactured device 120 is a package that comprises a package substrate 101, a flip-chip 102, an inductor 103 and a package molding 107.

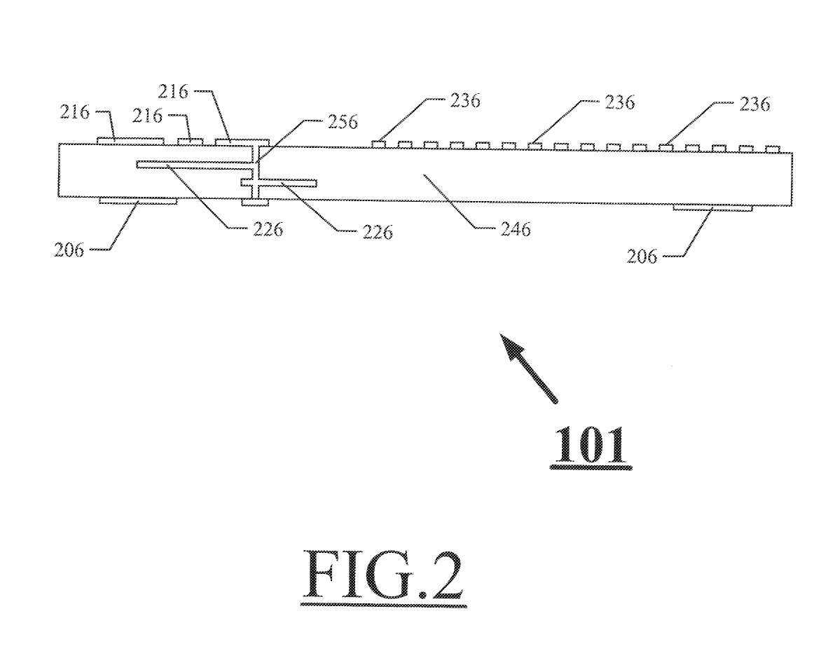

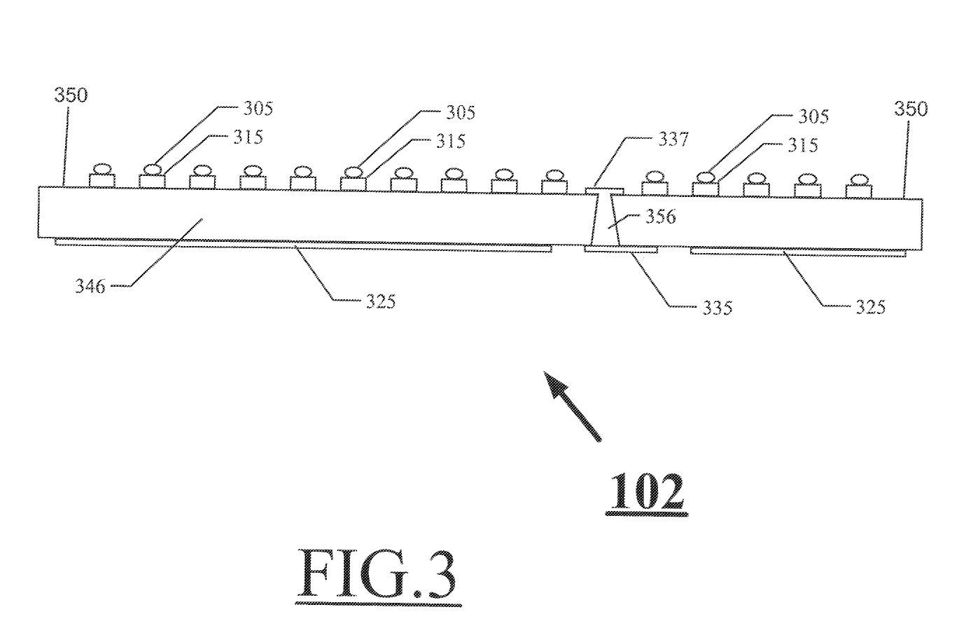

Still referring to FIG. 1, package substrate 101 may be a laminate PCB component as described in greater detail with reference to FIG. 2, below. Also, flip-chip may be as described below with reference to FIG. 3; it incorporates features that are novel in combination with aspects of the various exemplary embodiments of the invention. Package molding 107 may be a molded void-filling substance that is electrically non-conducting; the deployment of which is well known in the art. Inductor 103 may be a conducting wire, typically a solid (non-stranded) drawn metal wire having a good or excellent specific conductivity.

FIG. 2 shows a cross sectional view of a PCB-style (printed circuit board style) package substrate 101 as may be used to embody a part (101 of FIG. 1) of a complete device (120 of FIG. 1) according to an embodiment of the invention. A variety of different materials may be used to fabricate such package substrates 101. These materials will typically include insulating material 246 such as resin and other parts of the package substrate may comprise conducting material such as metal(s).

Non-conducting board materials 246 for RF (radio frequency) circuits are well-known in the art and may include types such as FR4, Rogers RT/Duroid, and/or Rogers R04003. Multiple grades and forms are available with disparate electrical properties and characteristics at various costs.

These materials can also be assembled in a variety of different ways potentially using multiple laminates, disparate materials and other features such as Damascene pattern conductors and plated through vias that are well known in the art. PCB conducting traces are typically made of copper but various finishes can be used by making use of materials such as Tin, Lead, Nickel, or Gold. Conducting pads 206 may be present on the external face of the package substrate to provide external interconnects for a complete device (120 of FIG. 1). Other conductors 216 may be external to the package substrate 101 but internal to the complete device.

Conducting vias 256 may also be present and if multi-layer laminated construction is used then buried conducting traces 226 may also be present. As shown in FIG. 2, a via 256 may be used to interconnect multiple buried traces 226 and/or to connect a buried trace 226 to a surface trace 216.

Conducting pads 236 may typically be provided for bonding a chip (not shown in FIG. 2) to the package substrate 101.

FIG. 3 shows a cross-sectional view of a flip-chip 102 according to an embodiment of the invention. Flip-chip 102 may be incorporated as part of a manufactured device (120 of FIG. 1). Flip-chip 102 will typically be fabricated from a Si, SiGe or complex III-V semiconductor material such as InGaP, GaAs/AlGaAs, InP, and GaN. It may comprise devices such as BJT/HBT (bipolar junction transistor/heterojunction bipolar transistor, HEMT (High electron mobility transistor) and/or FET (Field-effect transistor).

The exemplary device of FIG. 3 comprises a GaAs based die 346 that has been thinned to facilitate implementation of a via 356. The flip-chip 102 incorporates conducting metal chip pads 315 onto which conductive bumps 305 are formed. In a typical embodiment of the invention, bumps 305 are formed from a solder alloy, but other metals such as gold or copper have been used in other embodiments.

Conductive bumps are deposited on the chip pads 315 on what is at that time the top side 350 of the semiconductor wafer during one of the later steps in wafer processing. After dicing, when the die is ready to be mounted to the substrate (101 of FIGS. 1 and 2), the die is inverted (flipped over) so that the front surface, which is the erstwhile top surface with bumps 305 becomes the lower surface. Conversely, flipping causes the backside of the flip-chip to become the upper surface. Conductive bumps 305 are formed onto metal pads 315 only on the front surface of the flip-chip.

Flip-chip 102 incorporates one or more vias 356. To allow for electrical connections between front-side metal and a metal backside plane 325; via holes are formed and typically plated with gold to create the via (grounding via not shown in FIG. 3). Via holes that in this way pass all the way from front surface to the opposite (backside) of the flip-chip are termed “backside vias” in the art. Where vias connect to a metal backside plane 325 they can improve heat dissipation performance. The size of a via hole is determined responsive primarily to substrate thickness; for example a circular pattern having a 50- to 60-μm diameter is normally used on a 4 mils thick substrate. A plated gold layer may serve as the contact layer for die attach and a thermal path to a substrate.

Still referring to FIG. 3, backside via 356 connects not to a ground plane 325 but rather to a conductive pad 335 for attachment of a bondwire (not shown in FIG. 3). This type of backside via connects electrically to a front side conductive pad which in turn connects to active semiconductor regions formed in the front side of the die 346.

Flip-chip packaging technology has been used extensively used in the art. In flip-chip packaging techniques the front surface 350 of the die 346 becomes attached to a substrate. Conductive bumps 305 on the die match are deposited onto corresponding metal pads 315 on the front surface of the die. The conductive bumps are deposited on the metal pads on the front surface of the wafer during a late wafer process step. In order to mount the die to the substrate, the conductive bumps on the front surface are aligned with matching pads of the substrate (236 of FIG. 2). The conductive bump material is flowed or re-flowed to complete an interconnection between each pad supporting a bump on the die to a corresponding pad on the package substrate.

As well as providing for conductive interconnect between chip and substrate, bumps may also provide thermal conduction paths from chip to package substrate or PCB. Conductive bumps may also act as spacers such as for preventing electrical shorts between the die and substrate circuit and/or to provide mechanical support to the flip-chip. There exist well known processes in the art for implementing flip-chip bumps, for example so-called solder bumping, Au (gold) stud, and Cu (copper) stud bumping. Solder bumping is typically achieved by placing UBM (under-bump metallization) over bond pads such as by sputtering, plating, or similar means. Copper bumping is used more modernly; it provides good reliability, wide temperature range stability, mechanical strength, high connection density, excellent manufacturability, and superior electrical and heat-dissipating performance.

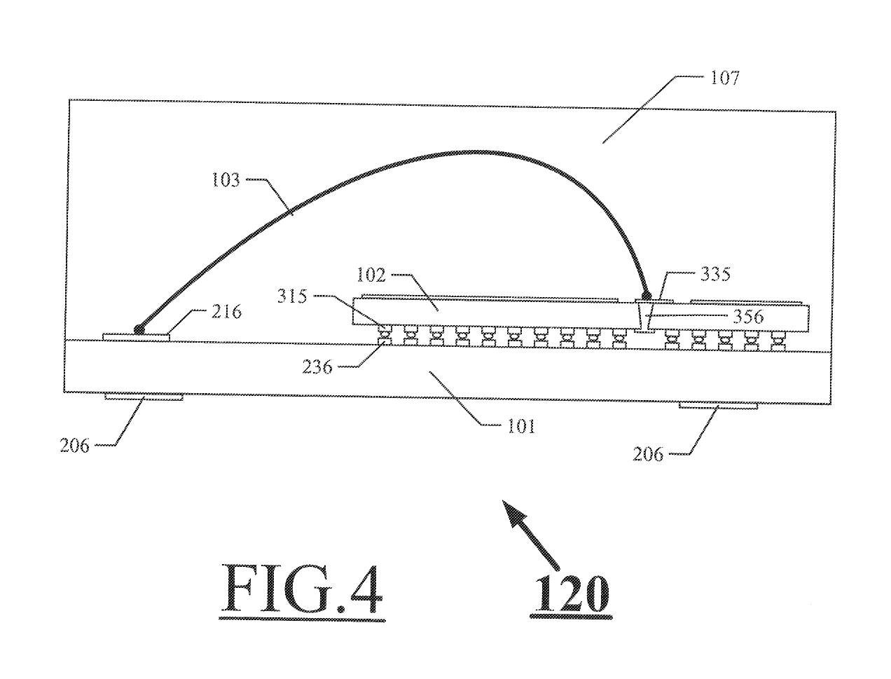

FIG. 4 shows a cross-sectional view of a complete device 120 according to an embodiment of the invention. Flip-chip 102 is shown in its mounted (inverted) position after inversion together with inductor 103. After inverting, flip-chip is aligned so that the pads 315 align with matching pads 236 of the package substrate 101. Inductor 103 is formed as a bondwire.

Although inductor 103 is formed as a bondwire, thus providing an inductance with a high Q. Complete device 120 may be formed without a leadframe thereby reducing size (as compared with previously developed leadframe implementations—and consequently improving performance). Wire bonding is relatively inexpensive and thereby cost-effective.

There are at least two types of wire bonding: Ball bonding, and Wedge bonding. Ball bonding usually is restricted to gold and copper wire and usually requires heat. Wedge bonding can use either gold or aluminum wire, gold wire requires heat, aluminum wire does not. Wire bond inductance is predictable and consistently a function of the length of the bond wire and its cross sectional area. Many bond wires are 25-30 μm in diameter and one to two millimeters in length. As a rule of thumb each mm of wire contributes about 1 nH to the inductance of bondwire. A commonly used manufacturing technique uses ball bonding for the die end of the bondwire and wedge bonding at the off-die end.

Still referring to FIG. 4, in an exemplary embodiment of the invention, inductor 103 is formed by ball bonding a gold wire 103 to conductive pad 335 connected to via 356 through the die; and by wedge bonding the gold wire 103 to surface trace 216 on package substrate 101. Surface trace 216 on package substrate 101 will typically be made from copper but a range of finishes can be used by deploying materials such as Tin, Lead, Gold, and Nickel.

Conducting pads 206 may be present on the external face of the package substrate to provide external interconnects for a complete device 120. Package molding 107 may be a molded void-filling inert substance to encapsulate the flip-chip die. The purpose of encapsulation is to protect electronic devices from adverse environments and/or to improve reliability and service life.

Other topologies and/or devices could also be used to construct alternative embodiments of the invention. The embodiments described above are exemplary rather than limiting and the bounds of the invention should be determined from the claims. Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A semiconductor device comprising:
a die having a front surface, a back side and a via for electrically connecting at least part of the front surface to at least part of the back side;
a bondwire connected to the back side and
a plurality of electrical interconnections formed on the front surface for connecting off the die.

2. The device of claim 1 wherein:
the front surface is substantially parallel to the backside.

3. The device of claim 1 wherein:
the plurality of electrical interconnections are flip-chip bumps.

4. The device of claim 1 further comprising:
a package substrate wherein the plurality of electrical interconnections are connected to the package substrate and the bondwire connects the package substrate to the back side.

5. The device of claim 3 further comprising:
a package substrate having a first surface connecting to the flip-chip bumps and further having a second surface providing interconnections external to the device.

6. The device of claim 1 wherein:
the bondwire is a radio frequency choke.

7. The device of claim 1 wherein:
the bondwire provides an inductance that resonates whenever the device operates.

8. A device comprising:
a flip-chip;
a bondwire and
a via that electrically connects the bondwire and two substantially opposite surfaces of the flip-chip.

9. The device of claim 8 further comprising:
a substrate that electrically connects the bondwire and a surface selected from a list consisting of the two substantially opposite surfaces of the flip-chip.

10. A device formed by:
creating a via through a die having first and second substantially flat surfaces;
connecting a bond wire to the first surface and
forming a plurality of conducting bumps on the second surface.

11. The device of claim 10 wherein:
the bondwire provides an inductance that resonates whenever the device operates.

12. The device of claim 10 wherein:
the bondwire is a radio frequency choke.

13. The device of claim 10 wherein the device is further formed by:
attaching a substrate that connects the bondwire to the plurality of conducting bumps.
